(19) United States
(12) Patent Application Publication
(10) Pub. No.: US 2019/0084077 A1
(43) Pub. Date: Mar. 21, 2019

(54) ELECTRONIC CIRCUIT BOARD AND ULTRASONIC BONDING METHOD

(71) Applicant: HONDA MOTOR CO., LTD., Tokyo (JP)

(72) Inventors: Tsugio Masuda, Tochigi (JP); Masaki Kunigami, Tochigi (JP); Nobuhiro Fueki, Tochigi (JP)

(21) Appl. No.: 16/083,145

(22) PCT Filed: Feb. 27, 2017
(86) PCT No.: PCT/JP2017/007531

§ 371 Date: Sep. 7, 2018

(30) Foreign Application Priority Data
Mar. 11, 2016 (JP) 2016-047921

(51) Int. Cl. B23K 20/10; H05K 1/14; H05K 3/32; H05K 3/36

(52) U.S. Cl. CPC B23K 20/10; H05K 3/36; H05K 3/32; H05K 1/14

(57) ABSTRACT

An electronic circuit board provided with a substrate, including a synthetic resin and having a conductor bonded to the upper surface, and an ultrasonic bonding method, the electronic circuit board and the ultrasonic bonding method enabling improved quality of bonding of another conductor to the conductor on the upper surface of the electronic circuit board. PCB (1) (an electronic circuit board) has a substrate (10) including first synthetic resin and a plurality of first conductors (11) bonded or attached to the upper surface of the substrate (10). The peripheral edge portion of the upper surface of each first conductor (11) is at least partly covered by a partial cover (12) (or an overlay) composed of second synthetic resin. The outer edge portion of the second synthetic resin constituting the partial cover (12) is integrally bonded to or in close contact with the first synthetic resin constituting the substrate (10).

### TECHNICAL FIELD

The present invention relates to a technology for bonding conductors to each other by ultrasonic vibration energy.

### BACKGROUND ART

There has been proposed a method for bonding a conductor coated with a synthetic resin to a conductor bonded to the upper surface of a substrate containing a synthetic resin by ultrasonic vibration energy (refer to, for example, Patent Literature 1). According to the method, in a state in which an object to be bonded has been held between a horn and an anvil, a synthetic resin that coats one conductor is first melted by the ultrasonic vibration energy of the horn so as to remove the synthetic resin from between two conductors, and then the two conductors are bonded to each other.

### CITATION LIST

### Patent Literature

Patent Literature 1: Japanese Patent Application Laid-Open No. 2005-223054

### SUMMARY OF INVENTION

### Technical Problem

However, if a synthetic resin constituting a substrate or an adhesive agent locally incurs a temperature increase and softens due to the ultrasonic vibration energy, then a part of the ultrasonic vibration energy is inconveniently absorbed by the vibration on the softened synthetic resin of the conductor placed on the substrate. Hence, the efficiency of the ultrasonic vibration energy to contribute to the bonding at the place where the two conductors are in contact deteriorates, leading to a possibility of an insufficient bonding strength of the two conductors.

Therefore, an object of the present invention is to provide an electronic circuit board provided with a substrate, which includes a synthetic resin and which has a conductor bonded to the upper surface thereof, and an ultrasonic bonding method, the electronic circuit board and the ultrasonic bonding method enabling an improved quality of bonding of another conductor to the conductor on the upper surface of the electronic circuit board.

### Solution to Problem

The present invention is an electronic circuit board provided with a substrate which includes a synthetic resin and a conductor bonded to the upper surface of the substrate. The upper surface peripheral edge portion of the conductor is at least partly covered by a synthetic resin constituting the substrate or another synthetic resin in close contact with the foregoing synthetic resin. In the electronic circuit board, at least a part of the exposed portion of the upper surface of the conductor is preferably covered by a metal that improves wettability of another metal that constitutes the conductor.

An ultrasonic bonding method according to the present invention is a method for ultrasonically bonding another conductor to the conductor bonded to the upper surface of the electronic circuit board according to the present invention, the ultrasonic bonding method including: a step of sandwiching, by a horn vibrated by a piezoelectric element and an anvil disposed opposing the horn, the electronic circuit board and the another conductor such that an exposed place of the upper surface of the conductor disposed on the electronic circuit board and the another conductor vertically overlap; and a step of displacing the horn downward while ultrasonically vibrating the horn in a horizontal direction so as to bond the conductor, which is disposed on the electronic circuit board, and the another conductor.

### Effect of the Invention

According to the electronic circuit board in accordance with the present invention, the upper surface peripheral edge portion of the conductor bonded to the upper surface of the electronic circuit board is at least partly covered by the synthetic resin constituting the substrate or another synthetic resin in close contact with the above synthetic resin. With this arrangement, even if the substrate locally incurs a temperature increase and softens due to the ultrasonic vibration energy of the horn, the vibration of the conductor bonded to the upper surface of the substrate is suppressed, thus leading to efficient contribution of the ultrasonic vibration energy to the bonding of the place of contact between the conductor (to be accurate, the exposed portion on the upper surface thereof) and the another conductor. Thus, the bonding strength between the conductor bonded to the upper surface of the electronic circuit board and the another conductor is improved, resulting in higher quality.

### BRIEF DESCRIPTION OF DRAWINGS

FIG. 1 is a diagram illustrating an upper surface of an electronic circuit board as an embodiment of the present invention;

FIG. 2 is a sectional view taken on line II-II in FIG. 1;

FIG. 3 is an explanatory diagram related to an ultrasonic bonding method as an embodiment of the present invention;

FIG. 4 is an explanatory diagram of the bonding between an electronic circuit board as an embodiment of the present invention and another conductor;

FIG. 5A is an explanatory diagram related to the results of evaluation of the bonding output of an electronic circuit board of a working example;

FIG. 5B is an explanatory diagram related to the results of evaluation of the bonding output of an electronic circuit board of a comparative example;

FIG. 6 is an explanatory diagram related to the results of evaluation of the tensile strengths of the electronic circuit board and the conductor; and

FIG. 7 is a diagram illustrating an upper surface of an electronic circuit board as another embodiment of the present invention.

### DESCRIPTION OF EMBODIMENTS

(Configuration)

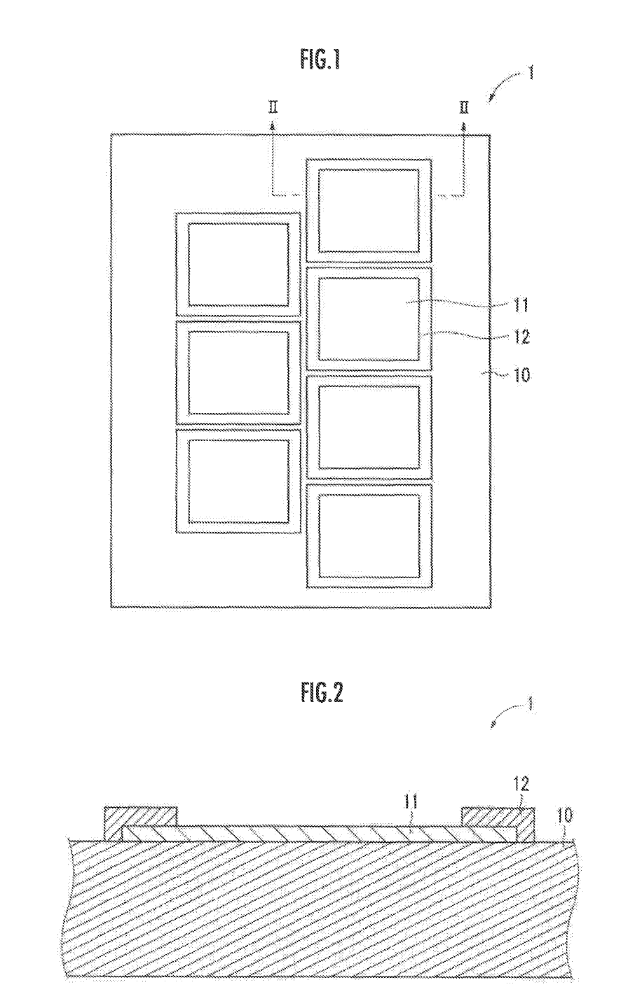

An electronic circuit board as an embodiment of the present invention illustrated in FIG. 1 and FIG. 2 is a PCB 1 (a printed circuit hoard or a printed wiring board), and has a substrate 10, which includes a first synthetic resin, one or a plurality of substantially tabular first conductors 11 bonded or attached to the upper surface of the substrate 10, and a partial cover 12 (or an overlay) composed of a second synthetic resin covering the full circumference of the upper surface peripheral edge portion of each of the first conductors 11. The first conductors 11 may be directly bonded to the substrate 10 or indirectly bonded to the substrate 10 through an adhesive agent.

The substrate 10 is, for example, an epoxy glass substrate, and an epoxy resin is used as the first synthetic resin. The metal constituting the first conductors 11 is, for example, Cu, Al or an alloy thereof. The partial cover 12 may be, for example, a synthetic resin of the same type as that of the first synthetic resin or a synthetic resin of a type that is different from the first synthetic resin. The outer edge portion of the second synthetic resin constituting the partial cover 12 is integrally bonded to or in close contact with the first synthetic resin constituting the substrate 10. On the upper surface of each of the first conductors 11, the portion on the inner side of the peripheral edge portion covered by the partial cover 12 is exposed, and another conductor is bonded or welded to at least a part of the exposed portion.

(Ultrasonic Bonding Method)

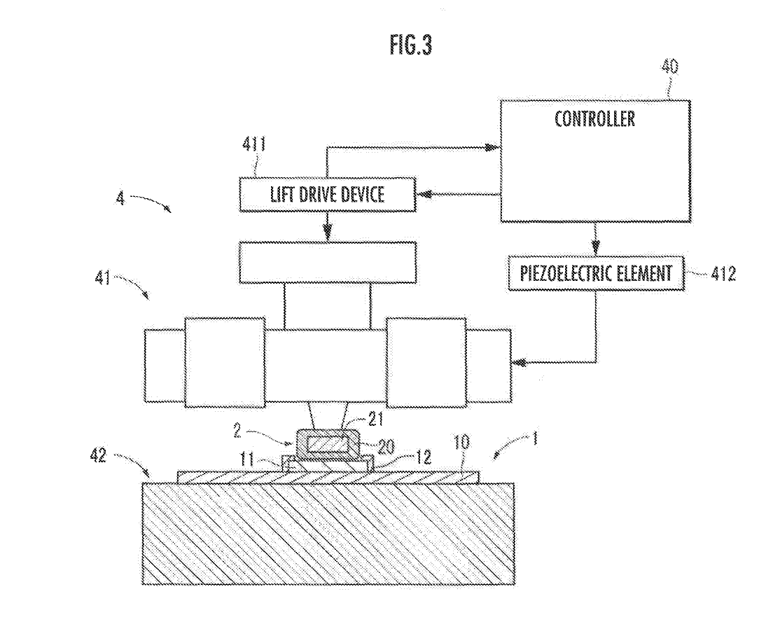

The following will describe the method for ultrasonically bonding an FFC 2 (flexible flat cable) to the PCB 1 by using an ultrasonic apparatus illustrated in FIG. 3. The FFC 2 includes a plurality of second conductors 21 and an insulating cover 20 which is composed of a synthetic resin and which provides covering that electrically isolates each of the plurality of second conductors 21.

An ultrasonic bonding apparatus 4 includes a horn 41 (or a chip), an anvil 42 opposed to and disposed under the horn 41, a lift drive device 411 which drives the horn 41 in a vertical direction, a piezoelectric element 412 (ultrasonic vibrator), which ultrasonically vibrates the horn 41, and a controller 40. The lower end portion of the horn 41 is formed to have a substantially truncated conical shape having its upper base facing downward; however, the shape of the lower end portion can be changed as appropriate to have, for example, a plurality of projections with belt-like or dot-like distal ends, according to how the conductors to be bonded are arranged. The upper end portion of the anvil 42 is substantially flat, but may be provided with projections and recesses, as appropriate, according to the shape of the horn 41.

The controller 40 is comprised of a computer (which includes a CPU (arithmetic processing unit), a memory (storage device), such as a ROM or RAM, an I/O circuit, and the like). The arithmetic processing unit reads necessary programs and data from the storage device to carry out the arithmetic processing, such as control of the operations of the lift drive device 411 and the piezoelectric element 412 according to the programs and the data.

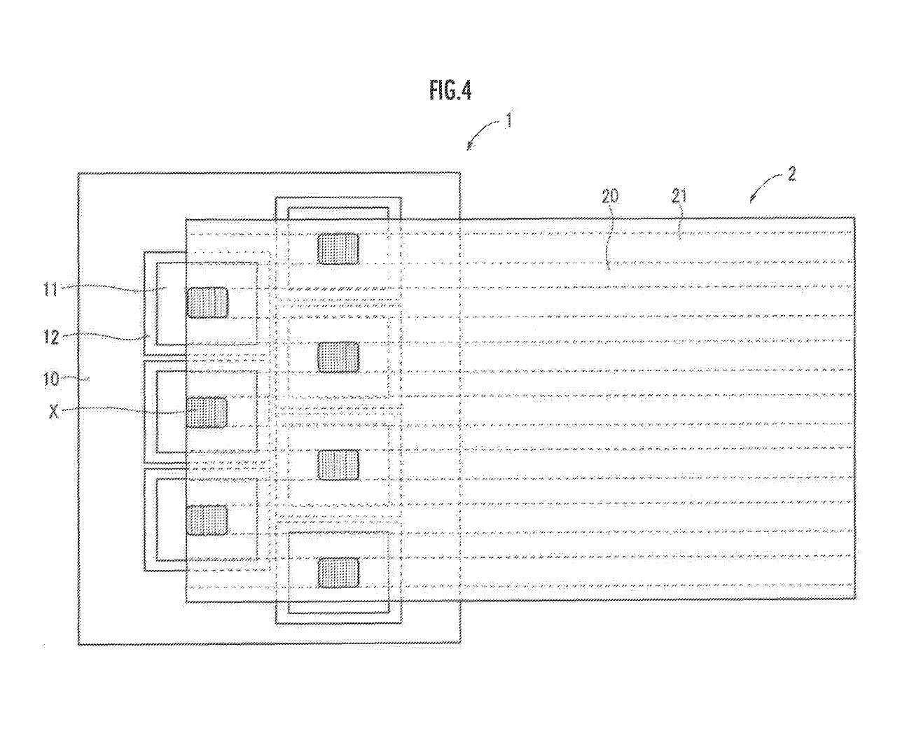

To ultrasonically bond the FFC 2 to the PCB 1, the PCB 1 and the FFC 2 are vertically stacked and held between the horn 41 and the anvil 42, as illustrated in FIG. 3. At this time, each of the first conductors 11 of the PCB 1 and each of the second conductors 21 of the FFC 2 are vertically stacked through the intermediary of the insulating cover 20 constituting the FFC 2 (refer to FIG. 4). In this state, the horn 41 is displaced toward the anvil 42 by the lift drive device 411 thereby to apply a load in the vertical direction to the PCB 1 and the FFC 2, and a high-frequency AC voltage is applied to the piezoelectric element 412 so as to ultrasonically vibrate the horn 41 (in the horizontal direction or in the lateral direction in the drawing).

The ultrasonic vibration energy of the horn 41 causes a local temperature increase at the places of the PCB 1 and the FFC 2 that are held between the horn 41 and the anvil 42, thus locally melting the insulating cover 20 of the FFC 2. The load in the vertical direction applied by the horn 41 and the anvil 42 gradually removes the molten synthetic resin derived from the insulating cover 20 from between the horn 41 and the anvil 42. At this time, the insulating cover 20 existing between the first conductors 11 and the second conductors 21 is also melted and gradually removed from between the first conductors 11 and the second conductors 21.

In the process of the removal of the molten synthetic resin derived from the insulating cover 20 from between the first conductors 11 and the second conductors 21, the second conductors 21 plastically deform and come in contact with the first conductors 11. The ultrasonic vibration energy of the horn 41 causes friction heat to be generated at the place of the contact, and the oxide films generated on the metal surfaces of the first conductors 11 and the second conductors 21 are removed, causing active surfaces (also referred to as “clean surfaces”) to be exposed and react. Then, after the bonding reaction (also referred to as “solid-phase bonding”) between the first conductors 11 and the second conductors 21 is completed, the lift drive or the ultrasonic vibration of the horn 41 is stopped. Thus, the PCB 1 and the FFC 2 are bonded at a bonding area X of each of the first conductors 11 and the second conductors 21 illustrated in FIG. 4.

(Effect)

According to the PCB 1 as an embodiment of the electronic circuit board of the present invention, the upper surface peripheral edge portion of each of the first conductors 11 bonded or attached to the upper surface of the PCB 1 is at least partly covered by the partial cover 12 formed of the first synthetic resin constituting the board or the second synthetic resin in close contact with the first synthetic resin. With this arrangement, even if the substrate 10 locally incurs a temperature increase and softens due to the ultrasonic vibration energy of the horn 41, the vibration of the first conductors 11 will be suppressed, so that the ultrasonic vibration energy efficiently contributes to the bonding of the places of contact of the first conductors 11 and the second conductors 21. Thus, the bonding strength of the first conductors 11 bonded to the upper surface of the PCB 1 and the second conductors 21 constituting the FFC 2 is improved, resulting in higher quality.

### Working Example

A first conductor 11, which is a square-shaped plate (3.0 [mm]×3.0 [mm] and 70 [μm] thick) made of Cu, was bonded onto the substrate 10 made of an epoxy glass resin, and a substantially square annular partial cover 12 having a 0.5-mm width was formed, covering the full circumference of the peripheral edge portion of the upper surface of the first conductor 11, thereby to fabricate an electronic circuit board of a working example.

### Comparative Example

An electronic circuit board of a comparative example was fabricated in the same manner as that of the working example except that the partial cover 12 was omitted.

(Evaluation)

The amplitude of the ultrasonic vibration of the horn 41 or the piezoelectric element 412 was controlled to three different values (65%, 75% and 85%, the maximum rated value of the amplitude being 100%) when the FFC 2 was bonded to the electronic circuit board of the working example and the electronic circuit board of the comparative example, respectively. The controller 40 carried out control such that the ultrasonic vibration energy (the amplitude) of the horn 41 was set to the above set values.

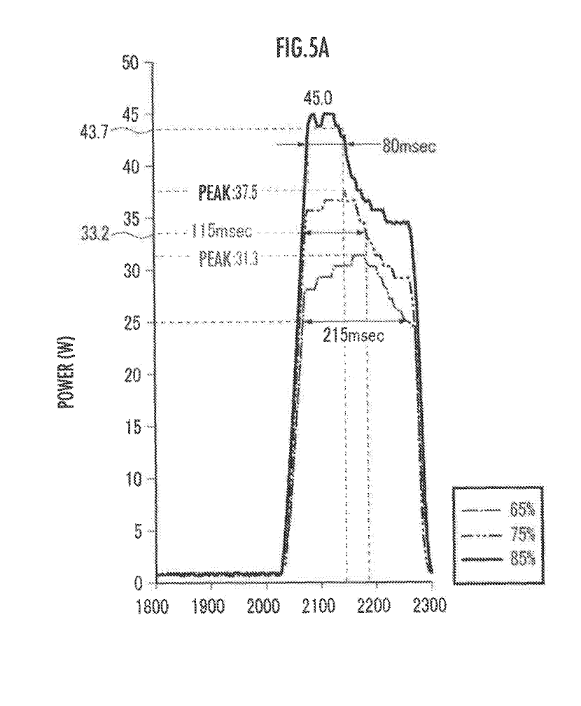

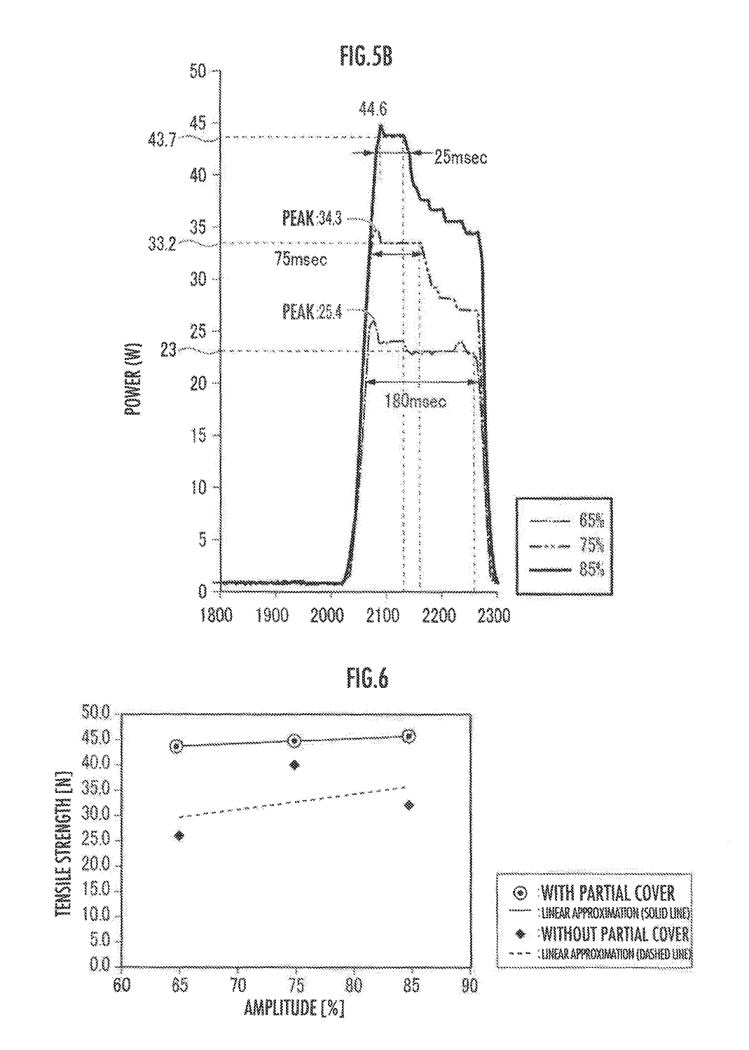

FIG. 5A and FIG. 5B illustrate how the ultrasonic vibration power of the horn 41 changed with time. The graphs illustrate the power (determined from the product of a voltage and a current), which was applied from the piezoelectric element 412 to cause the horn 41 to vibrate, in terms of the values measured as ultrasonic vibration power. As the ultrasonic vibration power was applied according to the set values and time elapsed, the melting and removal of the insulating cover 20 of the FFC 2 progressed. Subsequently, the first conductor 11 and the second conductor 21 came in contact, causing the ultrasonic vibration power to further increase, and the friction to which the horn 41 was subjected at the place where the horn 41 came in contact with the second conductor 21 led to the progress in the activation and the bonding reaction of the metal surfaces. The AC voltage applied to the piezoelectric element 412 was controlled by the controller 40 so as to obtain the foregoing amplitudes. Thereafter, upon the completion of the bonding reaction, the application of the ultrasonic vibration power was terminated and the apparatus stopped.

From FIG. 5A and FIG. 5B, it is seen that the peak value of the ultrasonic vibration power of the horn 41 is larger in the working example than in the comparative example (31.3 [W]>25.4 [W], 37.5 [W]>34.3 [W], and 45.0 [W]>44.6 [W]). Further, it is seen that the time during which high ultrasonic vibration power of the horn 41 is applied is longer in the working example than in the comparative example (215 [ms]>180 [ms], 115 [ms]>75 [ms], and 80 [ms]>25 [ms]). Each of the ultrasonic vibration power maintaining times was measured, with a first inflection point at which a peak value is reached after an initial rise being defined as the start point and an inflection point immediately before an end being defined as the end point. This indicates that the frictional force to which the horn 41 is subjected from the place of contact with the second conductor 21 when the first conductor 11 and the second conductor 21 come in contact with each other is greater and lasts longer in the working example than in the comparative example, meaning that the vibration of the first conductor 11 is suppressed by the partial cover 12.

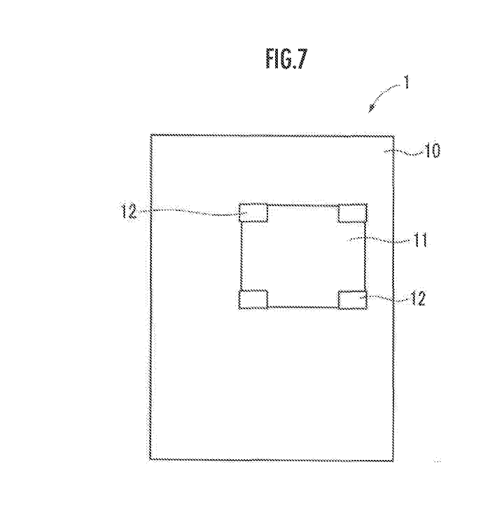

FIG. 6 illustrates the results of evaluation of the bonding strengths of the first conductor 11 and the second conductor 21 which have been bonded as described above. To measure the bonding strength, first, in a state in which the first conductor 11 bonded to the upper surface of the PCB 1 and the second conductor 21 constituting the FFC 2 has been solid-phase bonded by the ultrasonic vibration energy, these conductors are mounted on a PCB holding section configured under a tensile testing device such that the FFC 2 is perpendicular to the tensile testing device. Then, the FFC 2 is held by a lead wire fixing section provided on the drive section of the tensile testing device such that no tensile stress is generated in the FFC 2. From this state, the FFC 2 is pulled up in the vertical direction at a speed of 20 [mm/min]. The tensile strength of the second conductor 21 with respect to the first conductor 11, which is measured according to the method described above, was measured as the bonding strength. From FIG. 6, it is seen that the bonding strength is higher and the degree of correlation between the bonding strength and the ultrasonic vibration amplitude of the horn 41 is also higher in the working example than in the comparative example.

### Other Embodiments of the Present Invention

In the foregoing embodiment, the partial cover 12 covers the full circumference of the entire peripheral edge portion of the upper surface of each of the first conductors 11; however, as another embodiment, the partial cover 12 may intermittently cover a plurality of places of the peripheral edge portion of the upper surface of each of the first conductors 11. For example, the partial cover 12 may be provided to cover four places of the peripheral edge portion of the upper surface of each of the first conductors 11, the four places being apart from each other, as illustrated in FIG. 7.

At least a part of the exposed portion (the place not covered by the partial cover 12) of the upper surface of each of the first conductors 11 may be coated with a different metal (e.g. Ni) that increases the wettability of the metal (e.g. Cu or Al) constituting the first conductors 11. With this arrangement, when the first conductors 11 and the second conductors 21 locally melt, the molten metal derived from the first conductors 11 can be brought in contact with the metal constituting the second conductors 21 over a larger area; thus leading to higher bonding strength of the first conductor 11 and the second conductor 21. Further, the coating prevents the exposed portions of the upper surfaces of the first conductors 11 from being oxidized.

### DESCRIPTION OF REFERENCE NUMERALS

1 . . . PCB (Electronic circuit board); 2 . . . FFC; 10 . . . Substrate; 11 . . . First conductor (a conductor); 12 . . . Partial cover; 20 . . . Insulating cover; 21 . . . Second conductor (another conductor); 4 . . . Ultrasonic bonding apparatus; 40 . . . Controller; 41 . . . Horn; 42 . . . Anvil; 411 . . . Lift drive device; and 412 . . . Piezoelectric element (Ultrasonic vibrator).

1. An electronic circuit board comprising: a substrate which includes a synthetic resin; and a conductor bonded to an upper surface of the substrate,
wherein a peripheral edge portion of an upper surface of the conductor is at least partly covered by a synthetic resin constituting the substrate or by another synthetic resin in close contact with the synthetic resin.

2. The electronic circuit board according to claim 1,
wherein at least a part of an exposed portion of the upper surface of the conductor is covered by a metal that improves wettability of another metal that constitutes the conductor.

3. An ultrasonic bonding method for ultrasonically bonding another conductor to the conductor bonded to the upper surface of the electronic circuit board according to claim 1, comprising:
a step of sandwiching, by a horn vibrated by a piezoelectric element and an anvil disposed opposing the horn, the electronic circuit board and the another conductor such that an exposed place of the upper surface of the conductor disposed on the electronic circuit board and the another conductor are vertically overlapped; and
a step of displacing the horn downward while ultrasonically vibrating the horn in a horizontal direction so as to bond the conductor, which is disposed on the electronic circuit board, and the another conductor.
